(19) United States
(12) Patent Application Publication
(10) Pub. No.: US 2014/0027761 A1
(43) Pub. Date: Jan. 30, 2014

(54) THIN FILM TRANSISTOR SUBSTRATE, DISPLAY THEREOF AND MANUFACTURING METHOD THEREOF

(71) Applicant: INNOLUX CORPORATION, Miao-Li County (TW)

(72) Inventor: Cheng-Hsu Chou, Miao-Li County (TW)

(21) Appl. No.: 13/941,805

(22) Filed: Jul. 15, 2013

(30) Foreign Application Priority Data
Jul. 25, 2012 (TW) 101126770

(51) Int. Cl. H01L 33/44; H01L 29/66; H01L 29/786

(52) U.S. Cl. CPC H01L 33/44; H01L 29/7869; H01L 29/66742
USPC 257/43; 438/158

(57) ABSTRACT

A thin film transistor substrate includes a substrate and a plurality of thin film transistors. The thin film transistor includes a first electrode layer, a first insulating layer, an oxide semiconductor layer, a second electrode layer and a second insulating layer. The first electrode layer with gate portions is formed on the substrate. The first insulating layer covers the first electrode layer. The oxide semiconductor layer is formed on the first insulating layer, and the oxide semiconductor layer comprises a first boundary. The second electrode layer with drain portions and source portions is formed on the oxide semiconductor layer, wherein the drain portion and the corresponding source are corresponding gate portion, and the drain portion comprises a second boundary. The second insulating layer covers the oxide semiconductor layer and the second electrode layer. The second boundary is within the first boundary. The second electrode layer includes copper.

### BACKGROUND

1. Technical Field

The present disclosure relates to a display, in particular, to a thin film transistor substrate, a display thereof, and a manufacturing method thereof, wherein the thin film transistor substrate comprises copper and oxide semiconductor.

2. Description of Related Art

The thin flat liquid crystal displays (LCD) or organic light emitting diode (OLED) displays are widely used in the electronic devices due to the low power consumption thereof. A substrate of the active matrix liquid crystal display (AM-LCD) or active matrix organic light emitting diode (AM-OLED) display has a plurality of thin film transistors (TFT) thereon, and the thin film transistors are used to control the light emission rates of the pixels, such that the gray levels of the pixels are displayed.

Compared to the widely used amorphous silicon (a-Si) semiconductor, the thin film transistor with oxide semiconductor active layer, such as (Indium-Gallium-Zinc-Oxide, IGZO), has advantages of the greater electron mobility, lower power consumption, and smaller transistor area. Compared to the low temperature poly silicon (LTPS), the thin film transistor with oxide semiconductor active layer has advantages of the lower manufacturing cost and feasibility for high resolution large scale display.

In FIG. 1 which shows the cross section view of the thin film transistor substrate associated with the conventional display, the thin film transistor substrate 1 comprises a substrate 10 and a thin film transistor. The thin film transistor comprises a gate portion 11, a gate insulating layer 12, a metal interlayer 13, an oxide semiconductor layer 14, a source portion 15a, a drain portion 15b, a passivation layer 16, a contacting via 19, and a pixel electrode 17, wherein the material of the source portion 15a and the drain portion 15b is copper (Cu).

The patterned gate portion 11 is formed on the substrate 10. The gate insulating layer 12 is made of silicon oxide or silicon nitride (such as SiOx or SiNx), and fully covers the substrate 10 and the gate portion 10. The patterned oxide semiconductor layer 14 is on the gate insulating layer 12 and corresponding to gate portion 11.

To prevent the copper ions of the drain portion 15a and the source portion 15b from diffusing into the gate insulating layer 12 as mobile ions affecting the electric property of the thin film transistor and to increase the adhesive relation between copper and insulating layer, the metal interlayer 13 is formed on the gate insulating layer 12 and underneath the corresponding drain portion 15a and the corresponding source portion 15b.

The passivation layer 16 is made of silicon oxide or silicon nitride (such as SiOx or SiNx), and fully covers the drain portion 15a, the source portion 15b, the oxide semiconductor layer 14, and the gate insulating layer 12, to achieve protection and insulation effect. Next, the contacting via 19 is defined on the passivation layer 16, and then the pixel electrode 17 is formed on the passivation layer 16, wherein the pixel electrode 17 extends downward to electrically connect the source portion 15b through the contacting via 19.

Referring to FIG. 2, FIG. 2 is a cross section diagram of a thin film transistor substrate in another conventional display. Compared to FIG. 1, the thin film transistor of the thin film transistor substrate 1′ in FIG. 2 further comprises an etch stop layer (ESL) 18 formed on the oxide semiconductor layer 14, so as to prevent the etching process from damaging the back channel of the oxide semiconductor layer 14.

The metal interlayer 13 is made of molybdenum (Mo) or titanium (Ti) for example. After the gate insulating layer 12 is formed, molybdenum or titanium continuously deposits on the gate insulating layer 12, and fully covers the gate insulating layer 12. Then copper deposits on molybdenum or titanium, and then an etching process is performed to form the drain portion 15a, the source portion 15b, and the metal interlayer 13. However, in the etching process, part of molybdenum or titanium may not be completely etched, thus the electric property of the thin film transistor may be out of design, such that the reliability and yielding rate are affected.

### SUMMARY

An exemplary embodiment of the present disclosure provides a thin film transistor substrate comprising a substrate and a plurality of thin film transistors. The thin film transistor comprises a first electrode layer, a first insulating layer, an oxide semiconductor layer, a second electrode layer, and a second insulating layer. The first electrode layer is formed on the substrate and comprises a gate portion. The first insulating layer covers the first electrode layer. The oxide semiconductor layer is formed on the gate insulating layer, and the oxide semiconductor layer comprises a first boundary. The second electrode layer is formed on the oxide semiconductor layer, and comprises a source portion and a drain portion, wherein the source portion and the drain portion are corresponding to the gate portion, and the drain portion comprises a second boundary. The second insulating layer covers the oxide semiconductor layer and the second electrode layer, wherein the second boundary is within the first boundary, and the second electrode layer comprises copper.

An exemplary embodiment of the present disclosure provides a display comprising a display panel, a driving circuit, and an exterior part. The display panel comprises a thin film transistor substrate. The thin film transistor substrate comprises a substrate, a plurality of thin film transistors, a plurality of scan lines parallel to each other, and a plurality of data lines parallel to each other. The thin film transistor comprises a first electrode layer, a first insulating layer, an oxide semiconductor layer, a second electrode layer, and a second insulating layer. The first electrode layer is formed on the substrate and comprises a gate portion. The first insulating layer covers the first electrode layer. The oxide semiconductor layer is formed on the gate insulating layer, and the oxide semiconductor layer comprises a first boundary. The second electrode layer is formed on the oxide semiconductor layer, and comprises a source portion and a drain portion, wherein the source portion and the drain portion are corresponding to the gate portion, and the drain portion comprises a second boundary. The second insulating layer covers the oxide semiconductor layer and the second electrode layer, wherein second boundary is within the first boundary, and the second electrode layer comprises copper.

An exemplary embodiment of the present disclosure provides a manufacturing method of a thin film transistor substrate. Firstly, a substrate is provided. Then, a first electrode layer comprising a gate portion is formed on the substrate. Next, a first insulating layer is formed to cover first electrode layer. An oxide semiconductor layer is formed on first insulating layer, and the oxide semiconductor layer comprises a first boundary. Next, a second electrode layer comprising source portion and a drain portion is formed on the oxide semiconductor layer, wherein the source portion and the drain portion are corresponding to the gate portion. Finally, a second insulating layer is formed to cover the oxide semiconductor layer and the second electrode layer, wherein the second boundary is within the first boundary.

To sum up, the exemplary embodiments provide a thin film transistor substrate, a display thereof, and a manufacturing method thereof, wherein the second electrode layer of the thin film transistor is formed on the oxide is formed on the oxide semiconductor layer, and the adhesion between the second electrode layer and the oxide semiconductor layer is thus enhanced. Compared to the conventional thin film transistor, the second electrode layer of the thin film transistor in the exemplary embodiment of the present disclosure can be made of copper, and thus the metal interlayer is omitted. Accordingly, the thin film transistor has the lower cost, simpler process, larger yielding rate, and larger reliability.

In order to further understand the techniques, means and effects the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a cross section diagram of a thin film transistor substrate in a conventional display.

FIG. 2 is a cross section diagram of a thin film transistor substrate in another conventional display.

FIG. 3 is a cross section diagram of a thin film transistor substrate according to an exemplary embodiment of the present disclosure.

FIG. 4 is a layout diagram of a thin film transistor substrate according to an exemplary embodiment of the present disclosure.

FIG. 5 is a cross section diagram of a thin film transistor substrate according to another exemplary embodiment of the present disclosure.

FIG. 6 is a cross section diagram of a thin film transistor substrate according to another exemplary embodiment of the present disclosure.

FIG. 7 is a cross section diagram of a thin film transistor substrate according to another exemplary embodiment of the present disclosure.

FIG. 8 through FIG. 11 are layout diagrams of the semi-manufactured thin film transistor substrates respectively corresponding to steps of the thin film transistor substrate manufacturing method.

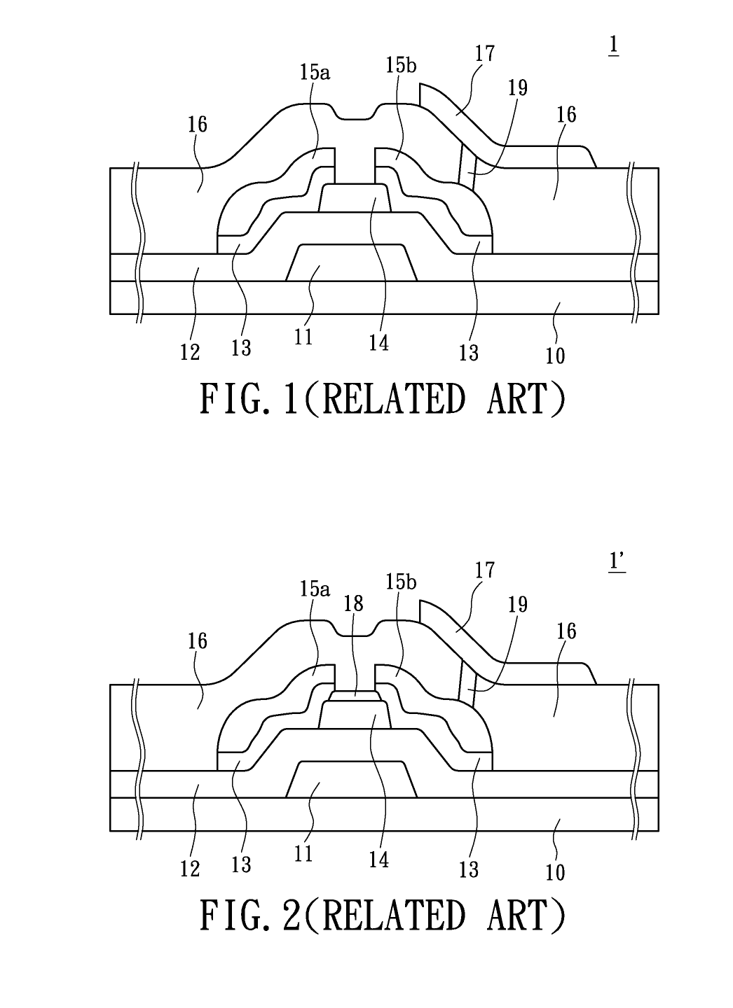

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or like parts.

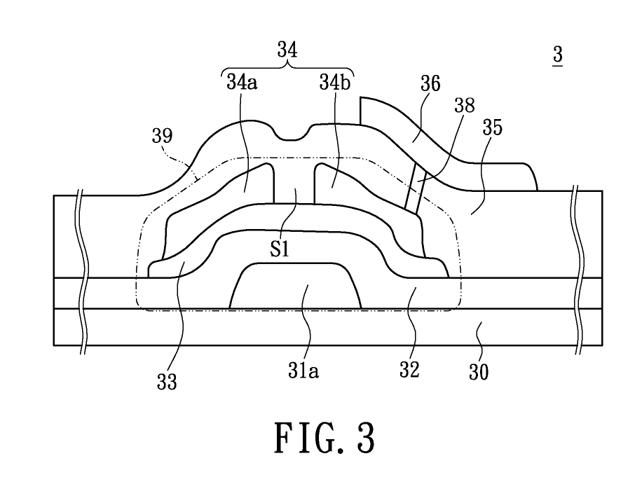

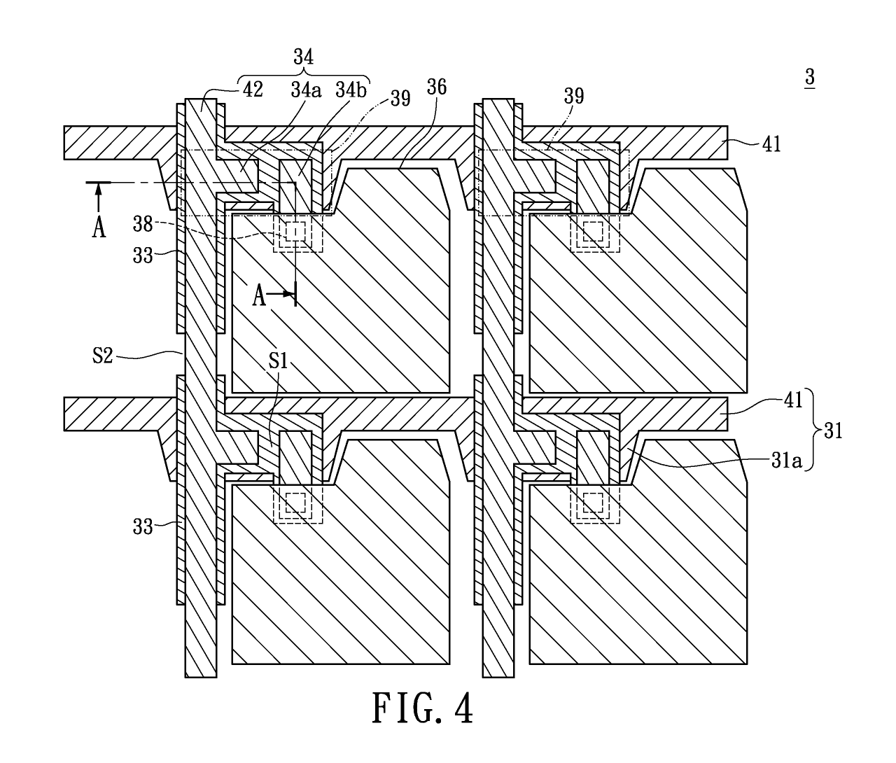

FIG. 3 is a cross section diagram of a thin film transistor substrate according to an exemplary embodiment of the present disclosure, and FIG. 3 is a cross section diagram of a thin film transistor substrate according to an exemplary embodiment of the present disclosure, wherein the cross section diagram of FIG. 3 is obtained from FIG. 4 along with the cross section line AA. The thin film transistor substrate 3 comprises a plurality of thin film transistors 39, a plurality of scan lines 41, and a plurality of data lines 42, wherein the thin film transistors 39 are arranged on the substrate 30 in an array manner, the scan lines 41 are parallel to each other and arranged along with a first axis (such as X axis), the data lines 42 are parallel to each other and arranged along with a first axis (such as Y axis). The scan lines 41 and the data lines 42 are intersected to form a plurality of pixel units. The thin film transistors 39 is located at the position which the scan lines 41 and the data lines 42 are intersected, so as to control the light transmission of the pixel units to display the gray level image through the driving signals provided by the scan lines 41 and the data lines 42.

The thin film transistor substrate 3 comprises a substrate 30, a thin film transistor 39, and a pixel electrode layer 36. The thin film transistor 39 comprises a first electrode layer 31, a first insulating layer 32, an oxide semiconductor layer 33, a second electrode layer 34, and a second insulating layer 35. In the exemplary embodiment, the thin film transistor 39 has a bottom gate structure.

The substrate 30 is used to support the thin film and components. The material of the substrate 30 is a transparent or opaque insulating material, such as glass, plastic, glass fiber, or metal foil covered with insulating surface.

The patterned first electrode layer 31 is located on the substrate 30, and has a conducting wire portion and a gate portion 31a, wherein the conducting wire portion can be the scan lines 41, and the gate portion 31 is protruding to the scan lines 41 or one part of the scan lines 41 to define the gate of the thin film transistor 39. The gate portion 31a and the scan line 41 are integral. The first electrode layer 31 can be a single layer, multiple layers. The material of the first electrode layer 31 can be aluminum, copper, molybdenum, titanium, silver, or magnesium in pure mode or alloy mode.

The first insulating layer 32 is also called the gate insulating layer, and is located on the first electrode layer 31 and the substrate. The first insulating layer 32 fully covers the first electrode layer 31 to electrically isolate the conduction between the electrodes and the channel of the thin film transistor. The material of the first insulating layer 32 can be SiNx, SiOx, or the combination thereof. However, the materials of the substrate 30, the first electrode layer 31, and the first insulating layer 32 are not used to limit the present disclosure.

The oxide semiconductor layer 33 is located on the first insulating layer 32, and partially covers the first insulating layer 32, wherein some part of the oxide semiconductor layer 33 corresponding to gate portion 31a is the channel of the thin film transistor. The oxide semiconductor layers 33 comprises a first boundary. The material of the oxide semiconductor layer 33 can be ionic bond semiconductor material having high mobility. The material of the oxide semiconductor layer 33 is for example ZnO, IZO, IGZO, ITZO, ATZO, HIZO, or the combination thereof. The oxide semiconductor layer 33 can be crystal state, poly-crystal state, or amorphous state.

The patterned second electrode layer 34 is located on the oxide semiconductor layer 33, and has the source portion 34b and the drain portion 34a respectively located at two opposite sides of the corresponding gate portion 31a. The source portion 34b and the drain portion 34a have a first gap Si therebetween, and are electrically insulated to each other, such that proper channel effect of the thin film transistor is generated. The drain portions 34a comprises a second boundary. The second electrode layer 34 further has the conducting wire portion which can be the data line 42. In the exemplary embodiment, the oxide semiconductor layer 33 is between the second electrode layer 34 and the first insulating layer 32, such that the semiconductor layer 33 is also served as the adhesion enhancing layer. The area of the oxide semiconductor layer 33 is equal or larger than that of the second electrode layer 34, and boundaries of the second electrode layer 34 are aligned to boundaries of the oxide semiconductor layer 33, or alternatively, the boundaries of the second electrode layer 34 are located within the boundaries of the oxide semiconductor layer 33. Actually, the second boundary of the drain portion 34a is within the corresponding first boundary of the oxide semiconductor layer 33. It is preferred that boundaries of the second electrode layer 34 are located within the boundaries of the oxide semiconductor layer 33. The pattern of the oxide semiconductor layer 33 under the data line 42 of the second electrode layer 34 has a second gap S2 to electrically insulate the possible conduction path of the oxide semiconductor layer 33, such that the leakage current is prevented from affecting the display. The material of second electrode layer 34 can be a single layer, multiple layers, or alloy of aluminum, copper, molybdenum, titanium, silver, and magnesium. In the exemplary embodiment, the second electrode layer 34 is a single layer of copper.

The second insulating layer 35 is located on the second electrode layer 34 and the oxide semiconductor layer 33, and fully covers the second electrode layer 34 and oxide semiconductor layer 33, so as to protect and insulate. The material of the second insulating layer 35 can be SiNx, SiOx, or the multiple layers of SiNx, SiOx. The structure from the first electrode layer 31 through the second insulating layer 35 is a complete thin film transistor 39 which is served as a switch.

It is noted that the material of the first insulating layer 32 can be SiNx, SiOx, and the other non-conducting material, the adhesion between the material of the first insulating layer 32 and the metal material of the second electrode layer 34 is poor, and the material of the oxide semiconductor layer 33 is ionic bond semiconductor material which has better adhesion between the metal material of the second electrode layer 34 and the non-conducting material of the first insulating layer 32. In addition, the oxide semiconductor layer 33 is served as the diffusion blocking layer to prevent the metal ions of the second electrode layer 34 on the oxide semiconductor layer 33 from entering the first insulating layer 32 under the oxide semiconductor layer 33, wherein the metal ions entering the first insulating layer 32 may form the mobile carriers which decreases the insulating property of the first insulating layer 32 and affects the reliability of the semiconductor component.

In addition, the oxide semiconductor layer 33 in the exemplary embodiment replace the metal interlayer, such that the problem that the remained metal of the conventional metal interlayer which is not etched during the etching process is solved. Since the second electrode layer 34 can be a single layer of copper, the selection of the etching solution and the etching process are simplified, and the remained metal is thus reduced. Compared to the prior art, the yielding rate of the thin film transistor substrate is increased, the process of the thin film transistor substrate is simplified, and the cost of the thin film transistor substrate is reduced.

Moreover, the second insulating layer 35 has the contacting via 38 corresponding to the source portion 34b (as shown in FIG. 4). The pixel electrode layer 36 is located on the second insulating layer 35, and covers part of the second insulating layer 35. The pixel electrode layer 36 extends downward to electrically connect the source portion 34b through the contacting via 38, such that the driving signal is received by the thin film transistor. The pixel electrode layers 36 of the pixels are electrically insulated, such that each thin film transistor 39 can drive independently to display the gray level image. After the structure from the first electrode layer 31 through the pixel electrode layer 36 is completed, the main part of the thin film transistor substrate is completed (p.s. other layers may be added in the thin film transistor substrate, and thus the thin film transistor substrate can have other features). The thin film transistor substrate is the main part of the display panel, and the thin film transistor substrate, the display layer (such as liquid crystal, organic electroluminescence, or electrophoresis), and the color filter substrate can form the display panel. The display panel, the driving circuit, and the exterior part can form the display.

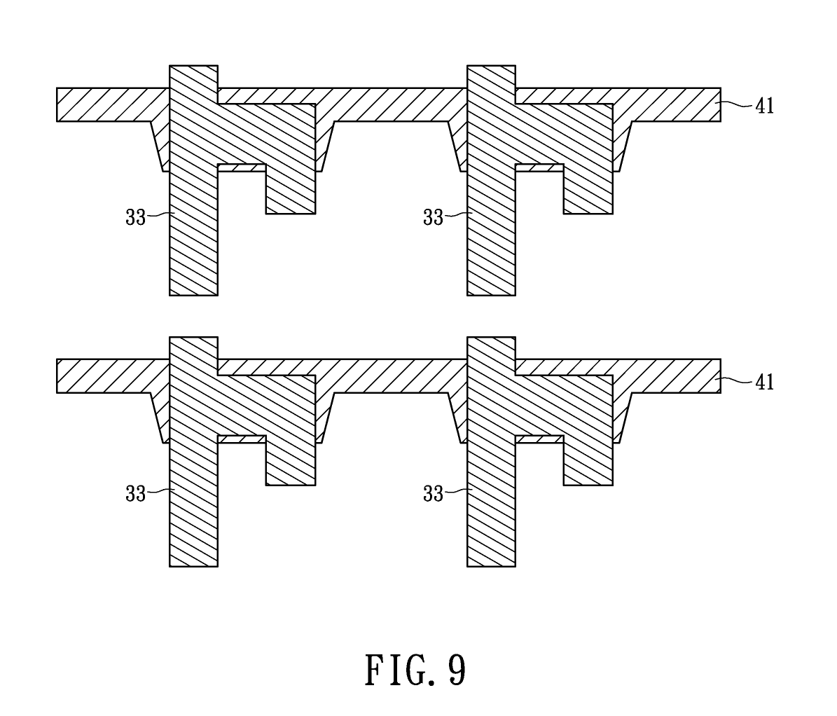

It is noted that the boundaries of the oxide semiconductor layer 33 in the exemplary embodiment may little excess (or be aligned to) the boundaries of the source portion 34b, the drain portion 34a, and the data lines 42. Moreover, the oxide semiconductor layers 33 under the data lines 42 can be electrically connected to each other, or electrically insulated to each other by having the second gap S2 (as shown in FIG. 9). In conclusion, the oxide semiconductor layer 33 in the other exemplary embodiment is not defined and fully covers the first insulating layer 32.

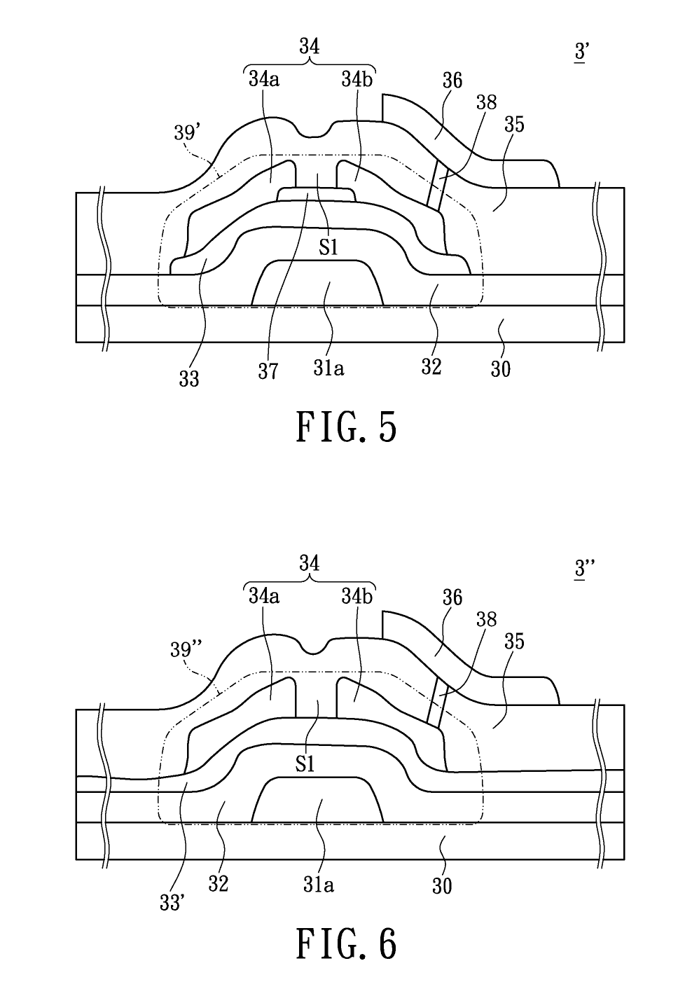

Referring to FIG. 5, FIG. 5 is a cross section diagram of a thin film transistor substrate 3′ of a liquid crystal display panel according to another exemplary embodiment of the present disclosure. Compared to the exemplary embodiment of FIG. 4, the thin film transistor 39′ in FIG. 5 further comprises an etch stop layer 37 formed on the oxide semiconductor layer 33. The etch stop layer 37 is corresponding and located between the source portion 34b and the drain portion 34a, such that the back channel of the of oxide semiconductor layer 33 is prevented from being damaged during the etching process, and the yielding rate and the conduction property of the thin film transistor are enhanced. The material of the etch stop layer 37 can be SiNx, SiOx, or the multiple layers of SiNx, SiOx.

Referring to FIG. 6, FIG. 6 is a cross section diagram of a thin film transistor substrate according to another exemplary embodiment of the present disclosure. Compared to the exemplary embodiment of FIG. 4, the oxide semiconductor layer 33′ of the thin film transistor 39″ wholly covers the first insulating layer 32 without being defined.

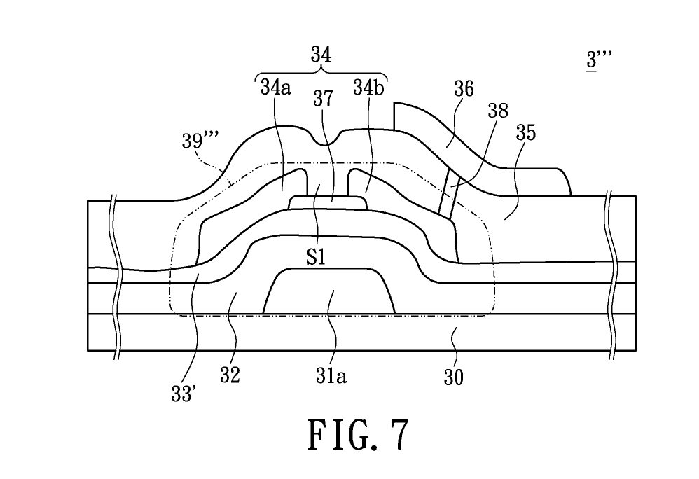

Referring to FIG. 7, FIG. 7 is a cross section diagram of a thin film transistor substrate according to another exemplary embodiment of the present disclosure. Compared to the exemplary embodiment of FIG. 5, the oxide semiconductor layer 33′ of the thin film transistor 39′″ wholly covers the first insulating layer 32 without being defined.

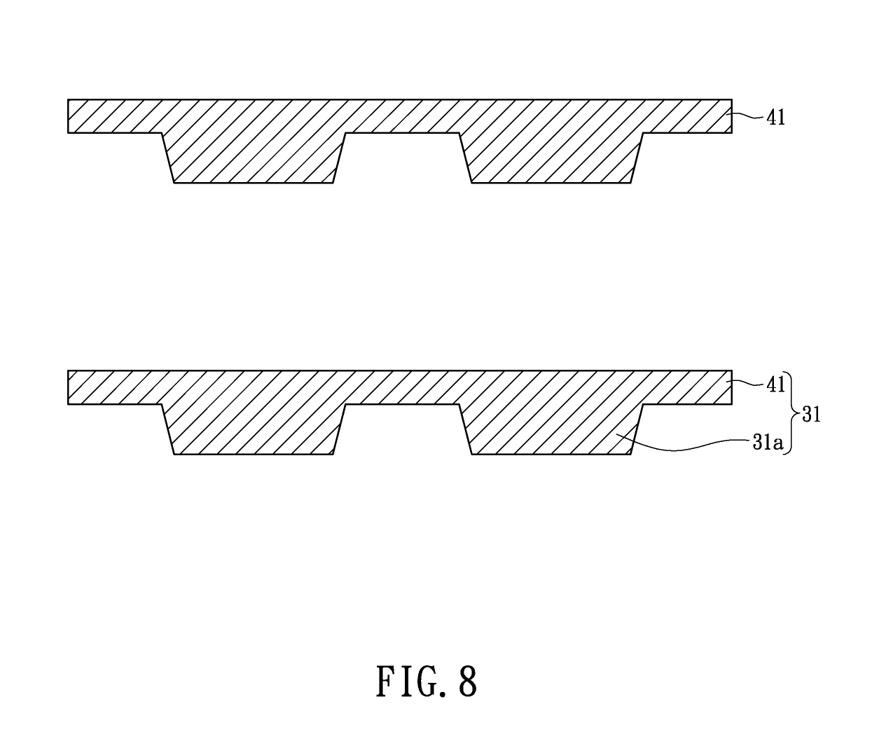

Referring FIG. 8 through FIG. 11 and FIG. 4 sequentially, FIG. 8 through FIG. 11 are layout diagrams of the thin film transistor substrates respectively corresponding to steps of manufacturing method. However, it is noted that the manufacturing method described as follows is merely one exemplary embodiment of the present disclosure, and the steps and orders of the method are not used to limit the present disclosure.

In FIG. 8, the substrate 30 is provided firstly. Then, a first electrode layer 31 on the substrate 30 is patterned to have a plurality of gate portions and scan lines (conducting wire portion), wherein the scan lines 41 are arranged along with a first axis, and each scan line 41 electrically connects the gate portions 31a. Next, the first insulating layer 32 is formed to cover the substrate 30, the scan lines 41, and the gate portion 31a.

Then, referring to FIG. 9, the oxide semiconductor layer 33 is formed on the first insulating layer 32. The oxide semiconductor layer 33 is defined, but in the other exemplary embodiments, the second gaps S2 may be added, or alternatively, the oxide semiconductor layer 33 is not defined.

It is noted that, in the other exemplary embodiment, the etch stop layer 37 may be further formed on the oxide semiconductor layer 33 which is located on the corresponding gate portion 31a.

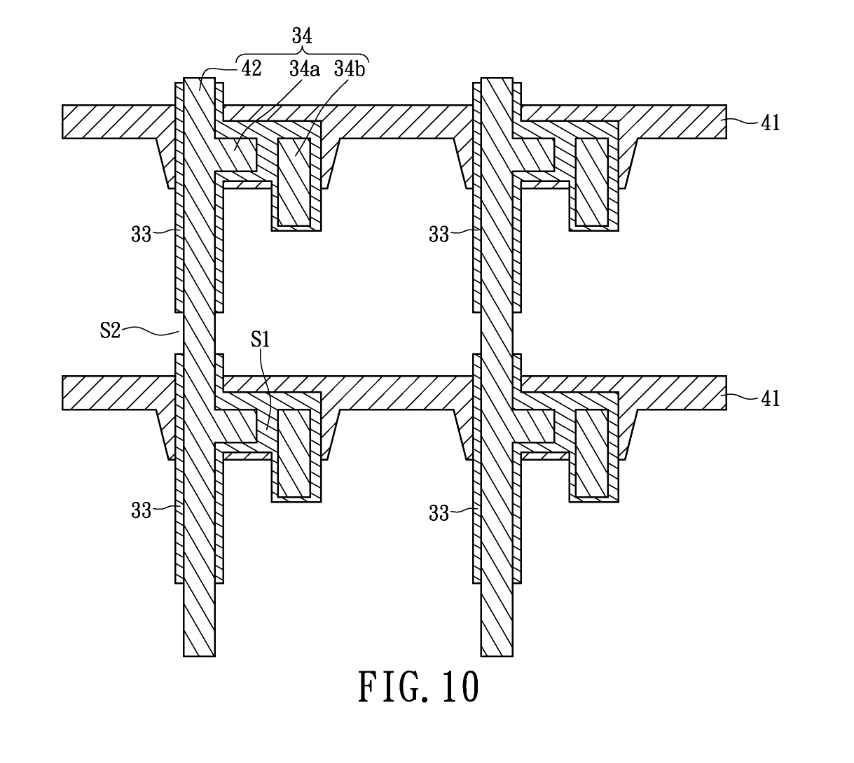

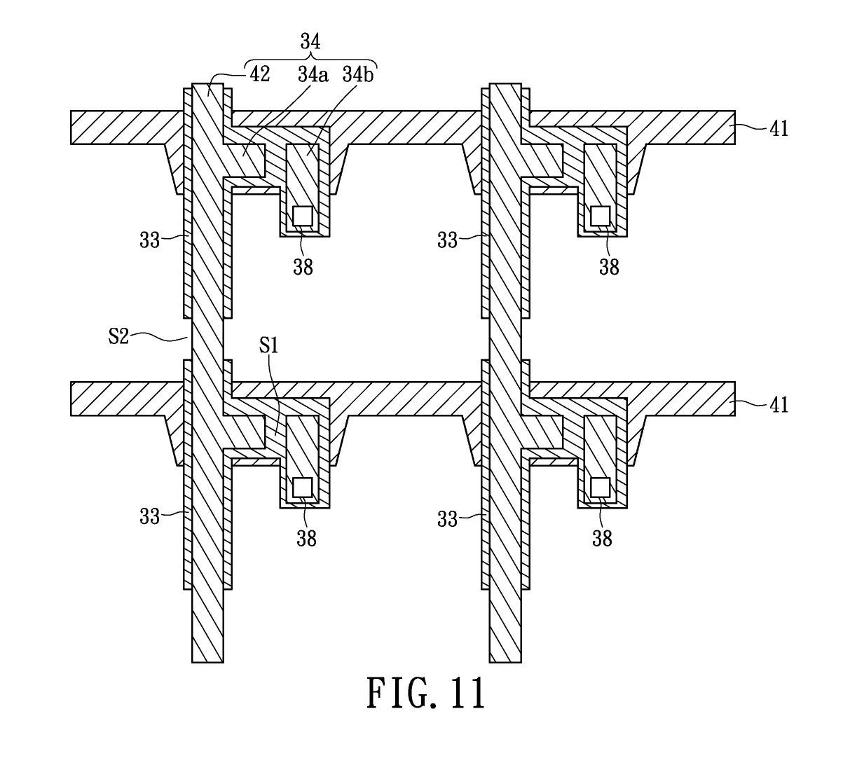

Then, referring to FIG. 10, the patterned second electrode layer 34 is formed on the oxide semiconductor layer 33, in which boundaries of the second electrode layer 34 are located within boundaries of the oxide semiconductor layer 33, and the second electrode layer 34 comprises a plurality of data lines parallel to each other, a plurality of drain portions 34a, and a plurality of source portions 34b having first gaps Si to the drain portions 34a. The data lines 42 are arranged along with the second axis, and each data line 42 electrically connects the drain portions 34a. Next, referring to FIG. 11, the second insulating layer 35 is formed and defined to generate a plurality of contacting vias 38. Finally, referring to FIG. 4, the pixel electrode layer 36 of the thin film transistors corresponding to the pixel regions is formed.

To sum up, the exemplary embodiments of the present disclosure provide a thin film transistor substrate, a display thereof, and a manufacturing method thereof, wherein the second electrode layer of the thin film transistor is formed on the oxide semiconductor layer, and the adhesion between the second electrode layer and the oxide semiconductor layer is better. Compared to the conventional thin film transistor, the simple copper is used to form the second electrode layer in the exemplary embodiment of the present disclosure, such that the metal interlayer can be omitted, and the simple metal etching solution is used to define the second electrode layer. Therefore, the thin film transistor has lower cost, simpler process, larger yielding rate, and better reliability.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A thin film transistor substrate, comprising:
a substrate;
a first electrode layer on the substrate, comprising a gate portion;
a first insulating layer, covering the first electrode layer;
an oxide semiconductor layer on the first insulating layer, the oxide semiconductor layer comprising a first boundary; and
a second electrode layer on the oxide semiconductor layer, comprising a source portion and a drain portion, wherein the source portion and the drain portion are corresponding to the gate portion, the drain portion comprising a second boundary;
wherein the second boundary is within the first boundary.

2. The thin film transistor substrate according to claim 1, wherein the oxide semiconductor layer fully covers the first insulating layer.

3. The thin film transistor substrate according to claim 1, wherein the oxide semiconductor layer is one of ZnO, IZO, IGZO, ITZO, ATZO, HIZO.

4. The thin film transistor substrate according to claim 1, wherein material of the second electrode layer is copper.

5. The thin film transistor substrate according to claim 1, further comprising an etch stop layer on the oxide semiconductor layer.

6. The thin film transistor substrate according to claim 1, further comprising a second insulating layer covering the second electrode layer and the oxide semiconductor layer.

7. The thin film transistor substrate according to claim 6, wherein the second insulating layer has a contacting via corresponding to the source portion.

8. The thin film transistor substrate according to claim 7, wherein the second insulating layer has a pixel electrode layer thereon, and the pixel electrode layer electrically connect the source portion through the contacting via.

9. A display, comprising:
a driving circuit; and
a display panel, comprising a thin film transistor substrate, wherein the thin film transistor substrate comprises:
a substrate;
a first electrode layer on the substrate, comprising a gate portion;
a first insulating layer, covering the first electrode layer;
an oxide semiconductor layer on the first insulating layer, the oxide semiconductor layer comprising a first boundary; and
a second electrode layer on the oxide semiconductor layer, comprising a source portion and a drain portion, wherein the source portion and the drain portion are corresponding to the gate portion, the drain portion comprising a second boundary;
wherein the second boundary is within the first boundary.

10. The display according to claim 9, the oxide semiconductor layer fully covers the first insulating layer.

11. The display according to claim 9, wherein the oxide semiconductor layer is one of ZnO, IZO, IGZO, ITZO, ATZO, HIZO.

12. The display according to claim 9, wherein material of the second electrode layer is copper.

13. The display according to claim 9, wherein the thin film transistor substrate further comprises an etch stop layer on the oxide semiconductor layer.

14. The display according to claim 9, wherein the thin film transistor substrate further comprises a second insulating covering the second electrode layer and the oxide semiconductor layer.

15. The display according to claim 14, wherein the second insulating layer has a contacting via corresponding to the source portion.

16. The display according to claim 15, wherein the second insulating layer has a pixel electrode layer thereon, and the pixel electrode layer electrically connect the source portion through the contacting via.

17. A manufacturing method of a thin film transistor substrate, comprising:
providing a substrate;
forming a first electrode layer comprising a gate portion on the substrate;
forming a first insulating layer to cover first electrode layer;
forming an oxide semiconductor layer on first insulating layer, the oxide semiconductor layer comprising a first boundary;
forming a second electrode layer comprising source portion and a drain portion on the oxide semiconductor layer, wherein the source portion and the drain portion are corresponding to the gate portion, the drain portion comprising a second boundary; and
forming a second insulating layer to cover the oxide semiconductor layer and the second electrode layer;
forming a contacting via corresponding to the source portion in the second insulating layer; and
forming a pixel electrode layer on the second insulating layer, wherein the pixel electrode layer electrically connected the source portion through the contacting via;
wherein the second boundary is within the first boundary.

18. The manufacturing method of the thin film transistor substrate according to claim 17, further comprising:
forming an etch stop layer on the oxide semiconductor layer.
